(19) United States
(12) Patent Application Publication
(10) Pub. No.: US 2022/0209045 A1
(43) Pub. Date: Jun. 30, 2022

(54) CMOS COMPATIBLE LIGHT EMITTING TUNNEL JUNCTION (LETJ)

(71) Applicant: The George Washington University, Washington, DC (US)

(72) Inventors: Volker J. SORGER, Alexandria, VA (US); Hasan GÖKTAS, Urla/Izmir (TR)

(21) Appl. No.: 17/606,507

(22) PCT Filed: May 11, 2020
(86) PCT No.: PCT/US2020/032347

§ 371 Date: Oct. 26, 2021

Related U.S. Application Data
(60) Provisional application No. 62/846,041, filed on May 10, 2019.

(51) Int. Cl. H01L 33/06; H01L 33/08; H01L 33/24

(52) U.S. Cl. CPC H01L 33/06; H01L 2933/0083; H01L 33/24; H01L 33/08

(57) ABSTRACT

A Light Emitting Tunnel Junction (LETJ) has a first layer, a second layer, and a gap layer disposed between said first layer and said second layer, forming a junction across which carriers tunnel upon being electrically biased. This so-biased tunnel junction gener ates light such as a photon, surface plasmon, or hybrids thereof either as a single light particle emitter denoting a quantum source, or emit ting a plurality of said light particles either spontaneously or stimulat ed (lasing). This tunnel junction light source may include an optical resonator and/or may couple its emission to a waveguiding or fiber system.

### CROSS-REFERENCE TO RELATED APPLICATIONS

This application claims the benefit of priority of U.S. Application No. 62/846,041 filed on May 10, 2019, the content of which is relied upon and incorporated herein by reference in its entirety.

### BACKGROUND

With the emergence of photonic integration, the challenges (a) to create light from silicon and (b) to realize electronically compact photonics have delayed the anticipated introduction of photonics into electronic consumer products. While the diffraction limit of light has been surpassed using polaritonic modes demonstrating device functionality such as modulation, light emission, detection, and tunable metasurfaces, the search for an electrically driven silicon-compatible light source operating at or above room temperature is yet outstanding. While silicon is capable of light emission, explored devices and emission mechanisms are challenged by operation instability and efficiency.

As a result, the light source requires heteromaterial integration, nanopatterned multilayer hyperbolic metamaterials, flip-chip bonding, or must be considered off-chip altogether. Other source-related challenges include temporal effects of the gain medium; with the spontaneous emission lifetime of semiconductors being about nanoseconds, any LED is limited to modulation rates of a ˜GHz. The time response of a laser, however, is limited by the gain relaxation oscillations but is still limited by optical nonlinear gain compression (gain saturation) effects to the GHz range. While the Purcell effect accelerates the spontaneous emission process raising the modulation frequency of a LED, it also reduces the laser threshold via improving the pump efficiency by increasing the spontaneous emission factor, β. Yet plasmon lasers require an inherently higher threshold power than photonic counterparts due to the lossy metals involved. This is physically logical since any polaritonic (matter-like) mode increases the loss of the cavity. Thus, if a nanometer small source is desired, high optical loss is unavoidable. Both inhomogeneous and homogeneous broadening effects are anticipated for our carrier-based tunnel junction source due to broadened density-of-states and collective carrier behavior of the involved plasmon polaritons.

Lastly, any on-chip light source should be electrically driven; this requires electrical contacts, which hinder integration density if any photonic mode is used due to the avoidance of optical losses. Taken together, the physical mechanism of using free-carrier recombination across a semiconductor band gap for light emission bears fundamental drawbacks limiting on-chip sources. As such, the demand for a silicon-based, nanometer small, potentially fast-modulatable, electrically driven on-chip light source operating at room temperature remains unmet to date. A possible solution is to use quantum tunneling and there are other examples related to or similar to MIS tunnel junction, however they sacrifice from very low fill factor and can take a large area due to having antenna coupled structures.

### SUMMARY

In contrast to the existing technology, here we demonstrate silicon-based and CMOS compatible room temperature Light Emitting Tunnel Junction (LETJ) with a high fill factor with small area and simple design that can enable high density circuit integration consequently less optical losses. Moreover, our design has 40-fold increase in the overall quantum efficiency with 10-fold increase in the internal efficiency. The design can achieve high modulation speed (>40 GHz) with sufficiently thin tunnel oxides (0.6 nm).

A Light Emitting Tunnel Junction (LETJ) has a first metal or semiconductor layer, a second metal or semiconductor layer, and a dielectric layer disposed between said first metal or semiconductor layer and said second metal or semiconductor layer. The dielectric lay forms an electrically biased barrier between the first and second layers. A power supply provides a bias voltage to the first and second metal or semiconductor layers. The bias voltage is selectively applied to induce a photon or phonon emission from the first metal or semiconductor layer.

This summary is not intended to identify all essential features of the claimed subject matter, nor is it intended for use in determining the scope of the claimed subject matter. It is to be understood that both the foregoing general description and the following detailed description are exemplary and are intended to provide an overview or framework to understand the nature and character of the disclosure.

### BRIEF DESCRIPTION OF THE FIGURES

The accompanying drawings are incorporated in and constitute a part of this specification. It is to be understood that the drawings illustrate only some examples of the disclosure and other examples or combinations of various examples that are not specifically illustrated in the figures may still fall within the scope of this disclosure. Examples will now be described with additional detail through the use of the drawings.

FIGS. 1(a), 1(c) show basic structure and working principle with possible light emission directions.

FIG. 1(b) shows silicon plasmon light source operation mechanisms and device details as a schematics of electrical bias scheme for the light-emitting tunnel junction based on a metal insulator semiconductor configuration, where the Metal: Au=100 nm. Oxide: SiO₂=tox=2.6±0.4 nm. Silicon: thickness=200 nm, p-type on a silicon-on-insulator (SOI) platform, and side-lengths of the squared devices vary from 0.5 to 40 μm.

FIG. 1(d) is an electrical bias scheme for the light-emitting tunnel junction based on a metal insulator semiconductor configuration

FIG. 1(e) is a spontaneous emission observed from the tunnel junction area

FIG. 2(a) is a schematic of elastically scattering tunneling.

FIG. 2(b) is a schematic of inelastically scattering carrier tunneling, leading to plasmon creation.

FIG. 2(c) shows the Light Emitting Tunnel Junction with only inelastic tunneling, where Layer 1 and Layer 3 can be Metal or Semiconductor, while Layer 2 is a dielectric layer.

FIG. 2(d) shows the Light Emitting Tunnel Junction with both elastic and inelastic tunneling, where Layer 1 and Layer 3 can be Metal or Semiconductor, while Layer 2 is a dielectric layer.

FIG. 3 shows subsequent subwavelength plasmon hybrid mode inside the junction. Highest |Ey|-field strength is inside the thin tunnel oxide. For surface normal emission, field density of the hybrid plasmons leak through the metal reaching the metal-air interface forming a surface plasmon polariton. When momentum is added, plasmons couple into free space.

FIG. 4(a) shows light emission to free-space coupling, in a schematic of etched device area using focused-ion-beam (FIB) milling to reduce the blocking top metal (Au, thickness=100 nm). d=etch depth. Inset: far-field CMOS images of the electroluminescence (EL) showing an optimum thickness.

FIG. 4(b) shows collected EL as a function of etched device pads (normalized for area, red squares). The exponential increase is due to the trivial loss reduction when the metal is thinned down. Gray area represents metal thickness. Optimum outcoupling thickness is about skin depth of metal.

FIG. 4(c) shows the spectrum and light emission profile for different duty cycle derived by Lumerical simulation, where a represents duty cycle and c represents the grating thickness.

FIG. 5(a) shows formula and indication for enhancement factor calculation. S=signal, BGK=background, MPNG=metal-pad-no-grating.

FIG. 5(b) shows sine shape and square shape gratings view under AFM.

FIG. 5(c) shows the EL enhancement for a sinusoidal grating yields an enhancement of up to 40 times. The degradation of the EL curve for high bias voltages is due to both imperfect MIS junction and thermal stress from joule heating.

FIG. 5(d) EL performance comparison of sine shape, square shape, and thin metal (skin depth) no-grating plasmon emitting tunnel junction in Lumerical FDTD simulation.

FIG. 6 shows thermal stress profile on oxide-metal interface cross section from top view for Au (20 nm)/SiO2 (2.5 nm)/Si (500 μm) at 8V.

FIG. 7 shows direct modulation speed of the tunnel junction. Results show that at 10s of GHz-fast modulation are possible for tunnel oxides less than one nanometer. MIS=metal-insulator-semiconductor and PIS=polysilicon-insulator-semiconductor. Inset: plasmon emitting tunnel junction layout and its equivalent circuit model.

FIG. 8(a) shows a combination of two devices together while creating an optical cavity between them to make much stronger light source like a laser.

FIG. 8(b) shows a combination of any two or more devices together while creating an optical cavity between them to make much stronger light source like a laser. Any two LETJ devices can be connected via optical cavity in any 6 different sides. This connection can be between two devices on just one surface, or up to 6 surfaces. Moreover, this can be applied to any LETJ in this figure, in another words, we can have an 3D array structure like Rubik's cube having n number of Single LETJ Unit connected to each other via optical cavity. Optical cavity here can be any type of medium, shape, structure and material (air, any other dielectric, semiconductor or metal, 0D, 1D, 2D, 3D, etc.). 2D layers here includes but not limited to ultrathin layers such as graphene, MoS₂, etc.

FIGS. 9(a)-(d) show that the Layers can be 3D, 2D (Nanosheet, 2D materials like graphene, MoS₂, etc.), 1D (nanotubes, Carbon nanotubes, etc.) or 0D (Quantum Dot, Metal Nanoparticles (gold nanoparticles, etc.), dielectric nanoparticles, etc.).

FIGS. 10(a)-(d) show configurations for the LETJ apparatus. Waveguides can be any type of medium, shape, structure and material (air, any other dielectric, semiconductor or metal, 0D, 1D, 2D, 3D, etc.). Waveguides can be connected to any sides where the light emission occurs (FIGS. 1(a), 1(b)).

FIG. 10(e)-(f) shows the two LETJ connected to each other via optical cavity in horizontal (FIG. 10(f)) and vertical (FIG. 10(g)) configuration

FIG. 10(g) demonstrates the possibility of building optical cavity with air in vertical configuration (FIG. 10(f)) with the help of 2D materials such as graphene.

FIG. 11(a) is a 1D array configuration.

FIG. 11(b) is a 2D array configuration.

FIG. 11(c) is a 3D array configuration

FIG. 12 shows the possible orientation for the LETJ device

### DETAILED DESCRIPTION

In describing the illustrative, non-limiting embodiments illustrated in the drawings, specific terminology will be resorted to for the sake of clarity. However, the disclosure is not intended to be limited to the specific terms so selected, and it is to be understood that each specific term includes all technical equivalents that operate in similar manner to accomplish a similar purpose. Several embodiments are described for illustrative purposes, it being understood that the description and claims are not limited to the illustrated embodiments and other embodiments not specifically shown in the drawings may also be within the scope of this disclosure.

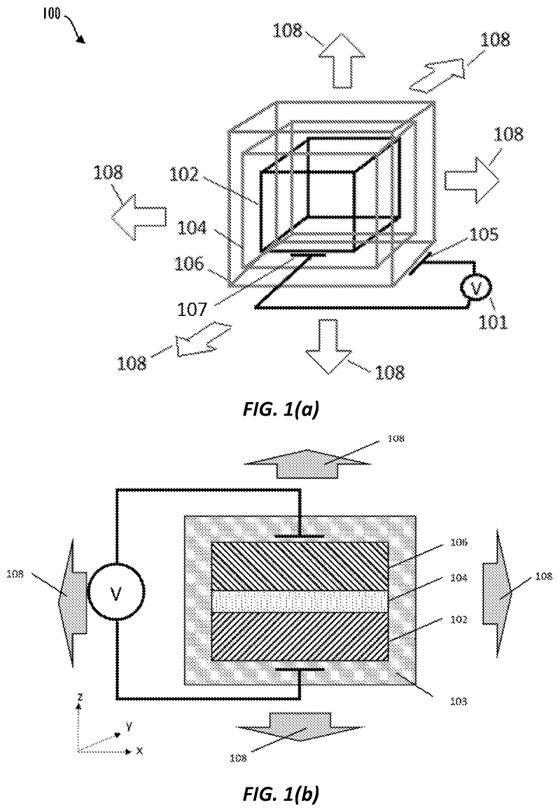

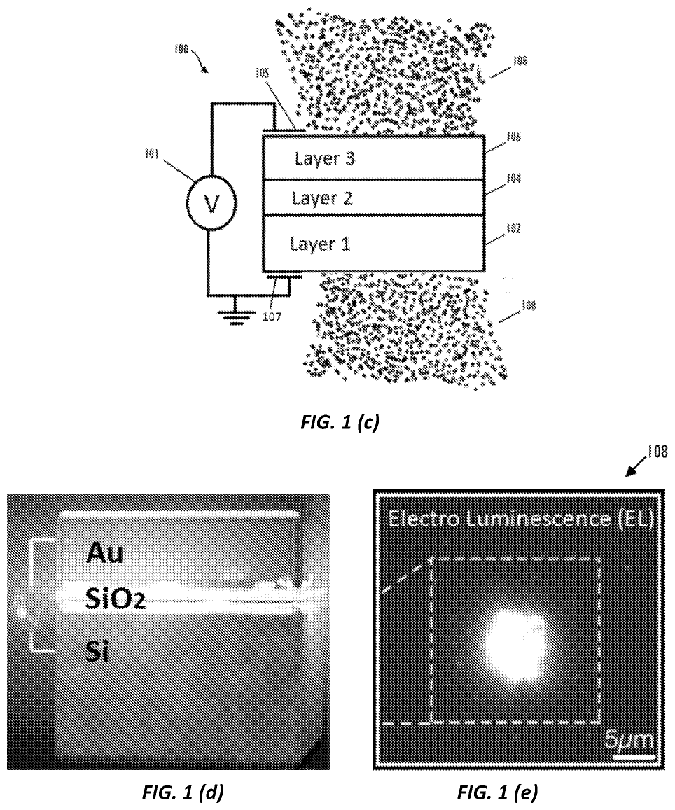

Turning to the drawings, FIGS. 1(a)-1(c) show an electrically driven, CMOS compatible, silicon-based plasmon on-chip source, also referred to here as a POC apparatus or a Light-Emitting Tunnel Junction (LETJ) apparatus 100, based on inelastic electron tunneling operating at room temperature in accordance with a non-limiting example embodiment of the present disclosure. Turning to FIG. 1, the light source 100 includes a p-silicon substrate 102, Layer 1, with a nanometer thin native oxide 104, Layer 2, topped with a noble metal electrode on a SOI substrate 106, Layer 3. The source has a metal-insulator-semiconductor (doped) (MIS) tunnel junction (i.e., Layer 2 forms a junction between Layer 1 and Layer 3) of a silicon-on-insulator (SOI) substrate, which supports a subwavelength plasmonic eigenmode. Applying a bias 101 at the junction shows a surface emission 108 that can be observed with the naked eye, or captured with a CCD camera (FIGS. 1(c), (d), (e)). This emission 108 is a plasmon-to-photon converted output assisted by the top-metal providing wavevector matching to free space.

Layer 1 (102), Layer 2 (104), Layer 3 (106), Electrical contact to Layer 1 (107), Electrical Contact to Layer 3 (105), Light Emission (108). Here we have light emission in all 6 direction (108) and any one of these (one-side, two-side, etc) or all directions (6 sides) can be used. Layer 1, Layer 2 and Layer 3 can be 0D, 1D, 2D and 3D and any combination among them (e.g., Layer 1 can be 3D and Layer 3 can be 1D, or a planar 2D Layer 1 interfaced with a 1D (wire) to form the LETJ (with a gap in between, Layer 3)). The structure can be even spherical shape rather than cubic shape to emit the light in literally every direction. Note, 108 does not have to emit in all 6 directions, but can emit in more or fewer directions depending on the dimensions of the LETJ and the desired application. The cladding 103 can be any materials, such as shown in Table 1.

TABLE 1
Options for the device ‘Cladding’ (103)

| | |
|---|---|
| Position | 1. One-side only |
| (relative to the | 2. Two-sides only |
| main LETJ | 3. N-sides only |
| device | 4. All (possible) sides |
| 102, 104, 106) | 5. All-permutations given the overall geometric |
| | shape of the LETJ, i.e. OD, 1D, 2D, 3D |
| Material Type | i. Metal |
| | ii. Oxide |
| | iii. Semiconductor |
| | iv. Dielectric |
| | vi. Semi-metal |
| | vii. Weyl fermion |
| | viii. Topological Insulator |
| | ix. Any combination thereof including stacked |
| | heterostructures |
| Function | A. Impedance matching e.g. to free-space to |
| performance by | neighboring waveguide, for example, anti |
| Cladding | reflection coating) |
| | B. Cavity or Resonator Feedback (e.g. for |
| | frequency selection, or, stimulated emission |
| | generation, lasing) |
| | C. Topological charge or ‘state’ (e.g. bound- |
| | state-in the continuum) |
| | D. Extended Electrical contact (e.g. for |
| | improved biasing) |
| | E. Heat Sync (e.g. for temperature |
| | augmentation) |

In other words, the basic LETJ structure includes 3 layers. Layer 1 and Layer 2 can be either Metal or Semiconductor, while Layer 2 is a dielectric layer. Layer 1 forms the bottommost layer and has a Layer 1 top surface and a Layer 1 bottom surface. Layer 2 is applied to the Layer 1 top surface and also has a Layer 2 bottom surface that directly engages the Layer 1 top surface, and a Layer 2 top surface. Layer 3 is applied to the Layer 2 top surface and has a Layer 3 top surface and a Layer 3 bottom surface. In the embodiment shown, each of the layers can be flat, thin and planar and substantially parallel to one another. And, the top and bottom surfaces of those layers can be flat and directly contact one another, e.g., at the Layer 1 top surface directly contacts the Layer 2 bottom surface, and the Layer 2 top surface directly contacts the Layer 3 bottom surface. When we apply a bias voltage 101 between (metal or semiconductor, etc.) Layer 3 and (metal or semiconductor, etc.) Layer 1 (e.g., to the Layer 1 bottom surface and Layer 3 top surface), this creates tunneling current and light emission 108. If there is no applied voltage 101, then there is no tunneling current and no light emission 108. The LETJ apparatus 100 can further include a housing that encloses the layers 102, 104, 106, and can also enclose the power supply 101.

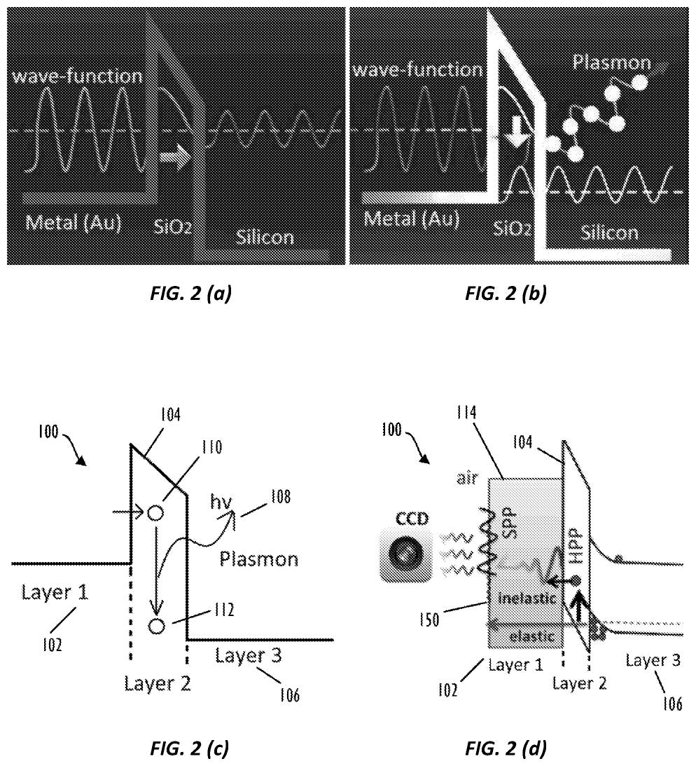

In one example embodiment, source-related bottlenecks can be avoided by turning to a different light creation mechanism. Referring to FIGS. 2(a)-2(d), for example, Layer 2 forms an electrically biased barrier 104, and the quantum tunneling of an electron is provided across that electrically biased barrier 104. Here, the electron can either tunnel elastically (FIG. 2(a), (d)), losing energy to phonon modes, or inelastically (FIG. 2(b), (c), (d)), creating a photon. The probability of the latter has been predicted to reach 10% for stimulated processes. This mechanism is interesting for light sources for two reasons; (a) since the temporal response upper limit of a tunnel event is governed by Heisenberg's uncertainty principle, the large optical energies of visible and NIR photonics demand sub psfast response times, and (b) if the final goal is to create a laser, the requirement for carrier population inversion of the gain material could be simply met by biasing two Fermi seas against a doped semiconductor; in a band diagram one then has 10²⁴ cm⁻³ carriers from the metal residing above the <10^{15 21} cm⁻³ carriers of the semiconductor Fermi level. If one is able to convert these 10³-10⁹ excess carriers into photons, a light source can be realized.

The underlying physical processes of this source are quantum mechanical elastic and inelastic electron tunneling across the barrier 104, FIGS. 2(a), (b).

In the elastic tunneling picture (FIG. 2(a)), a conduction electron in doped silicon approaches a biased, thin oxide barrier 104, which can be Layer 2 in one embodiment. With each scattering event at this barrier, there exists a finite probability that an electron will tunnel into the conduction band of the metal counter-electrode, conserving electron kinetic energy. After tunneling, the hot electron achieves thermal equilibrium with the electron sea via heat dissipation. Inelastic electron tunneling, in contrast, does not conserve electron energy. Instead, as shown in FIGS. 2(b), (c), (d), a photon or phonon is created as the electron transfers to a lower energy state in the metal counter-electrode. The dominance of elastic tunneling over inelastic tunneling determines the conversion efficiency. The latter can occur with a probability of up to 10% when optimized for materials and bias.

Thus, when bias voltage is applied, tunneling current creates both elastic and inelastic electron tunneling across the dielectric layer (i.e., the barrier) 104. In elastic electron tunneling, electron energy is conserved and no light 108 is generated. However, in inelastic electron tunneling, a photon or phonon 108 is created as the electron transfers (FIG. 2(c)) from a higher energy state 110 in Layer 1, to a lower energy state 112 in Layer 3. With the increase in the applied bias voltage 101, the electric field in dielectric layer 104 and tunneling current rise, creating hot electrons leading to emission events that feed two plasmonic modes asymmetrically. These are hybrid-plasmon mode (HPP) (via inelastic current tunneling) and the Surface Plasmon Polariton (SPP) (via elastically hot electron tunneling) (FIG. 2(a)). The emission intensity increases with the increase in the applied bias voltage 101.

Next, we show and discuss the observed electroluminescence when biasing the junction. By relating the emission to band-diagram under bias, we next explain the internal physics and operation principle of the source. The surface emission from the top metal 106, Layer 3 in one embodiment, (without a grating) is relatively weak and shows randomly distributed hot-spots originating from localized surface plasmons driven by random current fluctuations. The elastically tunneling electrons found spatial overlapping with the high-field density of the high k-vector hybrid-plasmon mode. Thus, the only optical mode to be excited is the hybrid plasmon polariton mode. These photon-plasmons leak through the top metal 106, experiencing losses. Upon reaching the sample surface (metal-air interface), they form a surface plasmon polariton. The latter has high impedance to free-space; however, the grain boundaries of the electron-beam evaporated metal film (RMS_{Au}=5-10 nm) add momentum to the plasmons and thus scatter into free space. As such, the external conversion efficiency of these MIS tunnel junction sources is understandably low and observed to be <10⁻⁵. While improvements in the outcoupling efficiency is an engineering challenge, we first turn our attention to analyzing and validating the light creation mechanism.

The overall quantum efficiency (ηwallplug) of the light emitting tunnel junction's emission is given by the product of two factors; namely, the internal light (here plasmon) creation (ηint) times an outcoupling efficiency (ηoutcouple) factor, simply via

ηwallplug=ηint·ηoutcouple

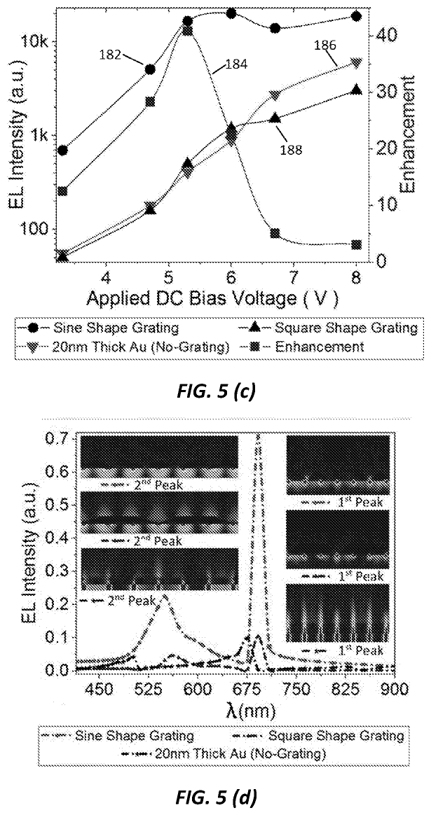

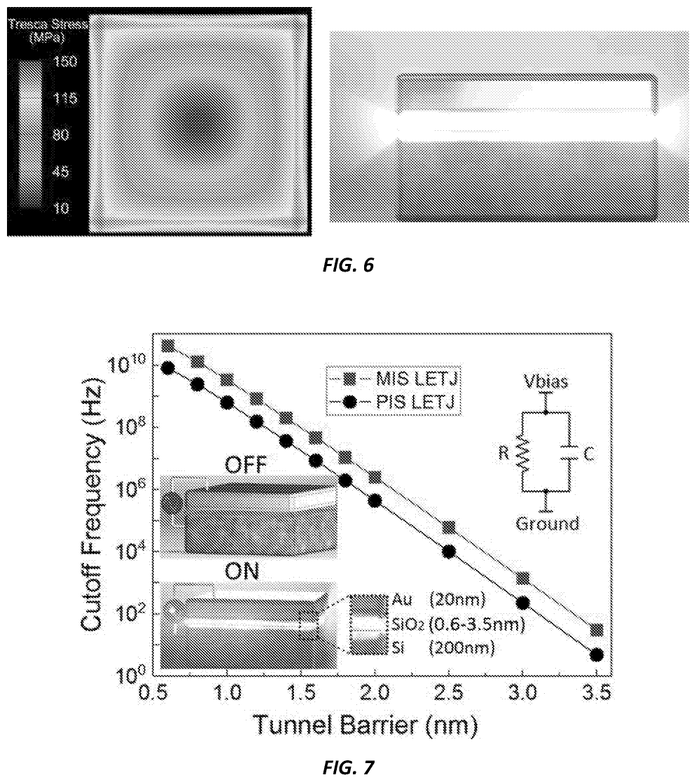

ηwallplug is measured to be 4.8(±3.5)×10⁻⁴ and ηint is measured to be O≈10⁻⁴, where ηoutcouple is outcoupling efficiency and ηint is internal efficiency. In one embodiment of the invention, ηoutcouple is 4, ηint is 10, and ηwallplug is 40. The ηoutcouple is constant and 4 for sine shape grating, as it only depends on the grating structure. However, we may generalize this by saying; ηoutcouple 1-X depending on the grating structure. Here X can be any number. However, ηint is not constant and varies with the applied bias voltage. The limit here is 10 (at Vbias=5.3 V). If we exceed this temperature then the thermal stresses (FIG. 6) due to relatively high temperature results in device failure. If we decrease the temperature via new high thermal conductive design then possibly, we can increase the lint. It may go over 10. In short, in this current form and sine shape grating design, we can say dint can vary between 1-40 (184, FIG. 5c) by changing the applied bias voltage (Vbias). However, we may generalize this by ηint 1-Y depending on the maximum thermal stress and grating structure. Here Y can be any number. Overall, ηwallplug is 1-Z, depending on the maximum thermal stress and grating structure. The ηwallplug is 4-40. Here Z can be any number.

Here, as represented in FIG. 2 the internal quantum efficiency is related to the source's internal mechanism, and this can be explained by a combination of the band diagram, tunnel current, and subsequent conversion into plasmonic modes under different biasing conditions. Electrically the junction is equivalent to a capacitor with a parallel tunnel resistor. The capacitor formed by the MIS stack has the three-known operation regimes from which accumulation (negative bias) and inversion (positive bias) are of importance for tunneling. Under forward bias to the metal, the semiconductor bands bend downward (inversion) facilitating gate tunneling leakage current (I₂) from the metal to p-type silicon. Changing the bias polarity results in upward band bending; here, the accumulated holes tunnel across the electrostatically thinned oxide either elastically or inelastically (I₁). This asymmetry leads to an accumulation-current magnitude that is significantly higher relative to the gate tunneling leakage current I₂ under inversion.

With applied bias voltage 101, the electric field and I₁ rise, creating hot electrons leading to emission events that feed two plasmonic modes asymmetrically. Light emission originating from I₁ feeds both the hybrid-plasmon mode (via inelastic current tunneling) FIGS. 2(b), (c), (d), and the surface plasmon (via elastically tunneling hot electrons) (FIGS. 2(a), (d). The hybrid plasmon mode inside the junction is hidden from sight unless accessed otherwise (i.e., scattered out). These hybrid plasmons propagate through the top metal from where they scatter into free space via momentum added by the metal roughness.

We experimentally demonstrated an electrical-driven silicon based plasmon source where the plasmon creating mechanisms originates from inelastically tunneling electrons across a quantum barrier comprising a thin dielectric. This light emitting tunnel junction is not bound by physics of a classical semiconductor two-level system, but by the probability of plasmon creation from inelastically tunneling electrons.

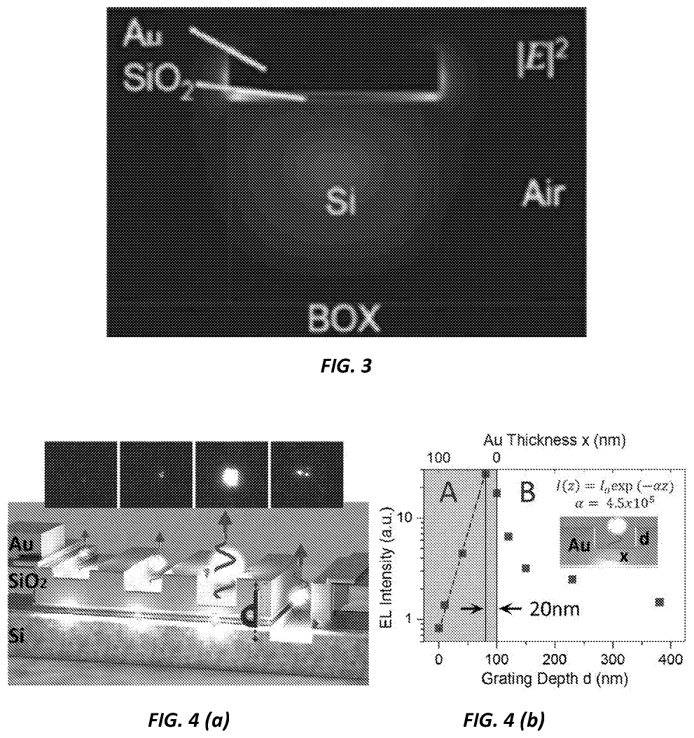

Such a metal/low-dielectric/high-dielectric structure supports a hybridized mode between a classical photonic waveguide and a surface plasmon polariton when placed on a low-index substrate (FIG. 3). This geometry acting as an optical capacitor is able to confine light below the diffraction limit of light down to (λ/20)² at visible and NIR frequencies, while exhibiting a high electric field density inside the oxide gap. This field density has an impact at the internal conversion process of the device as discussed below since the tunnel current responsible for photon (here plasmon) generation increases with the electric field.

Verifying the origin of the hypothesized photon emission process to the tunnel current, we obtain the current-voltage (I-V) characteristics and relate it to the integrated EL. Our results show that the I-V characteristic matches Fowler-Nordheim tunneling models. The DC tunneling current responsible from light emission increases with applied bias voltage (Vbias) due to a higher electric field, which elevates the field densities of the two plasmonic modes by way of creation of hot electrons and thus the observed electroluminescence intensity. We find that both the current (measurement and simulation) and corresponding EL intensity track each other well, thus verifying that the tunnel current is indeed the origin for the plasmon creation. The tunnel current density responsible from the plasmon emission is proportional to the electric field in the oxide layer.

$$I α {E}_{i}^{2} exp [ - \frac{4 \sqrt{2 {m}^{*}} {( q {ϕ}_{B} )}^{3 \text{/} 2}}{3 {qhE}_{i}} ] \qquad ( 1 )$$

That is why internal efficiency is related and proportional to the hot electron creation via electric field (Eᵢ) enhancement facilitated by the hybrid photon plasmon mode. The electric field in the insulator region is proportional to the surface potential and given in (2) as;

$${E}_{ox} = ( {V}_{bias} + {ϕ}_{Bs} - {ϕ}_{Bm} + \frac{{k}_{B} T}{e} ln ( \frac{{N}_{C}}{{N}_{D}} ) - {ψ}_{s} ) \text{/} {t}_{ox} \qquad ( 2 )$$

where Vbias is the applied bias voltage, ϕBs is the difference between the electron affinities of Si and SiO₂, ϕBm is the difference between the electron affinity of SiO2 and the work function of the metal, tox is the oxide thickness and ψs is the surface potential. Both an increase in the tunneling current (eq. 1) or an increase in the applied bias voltage (eq. 2) result in a higher electric field in the insulator region. Up to certain point, the tunneling current is ignorable and very small, however it shows a threshold effect in the IV curve when the electric field is high. This is accompanied by an increase in the light emission intensity.

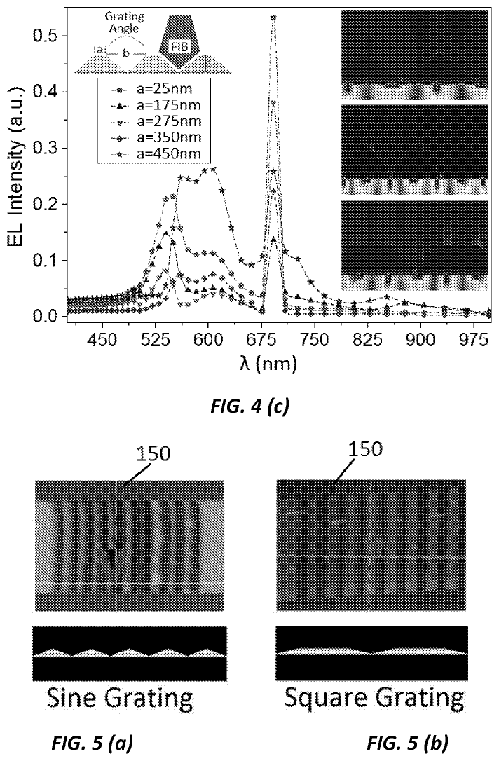

Indeed, biasing two Fermi levels against one another across a thin tunnel oxide (metal-insulator-metal (MIM)) shows faint light emission. The emission observed through the 10-100s nm thick top metal is expected to be miniscule and is hence a poor indicator of the internal photon conversion efficiency of the tunneling process. Lowering the device to cryogenic temperatures or reducing the metal thickness (FIGS. 4(a), (b)) shows some emission improvements.

We show that the free-space detected photons originate from plasmons generated inside the source, which are converted into photons via coupling effect between electric field enhancement (internal efficiency) and grating design (outcoupling efficiency). Accessing the dense plasmonic modes hidden underneath the metal layer via selective etching reveals high-field densities inside the device. We find an optimum top contact thickness close to that of the skin depth of the junction metal. We find the ideal metal thickness of this

metal-insulator-semiconductor junction to coincide with the skin depth of the metal used (FIG. 4(b)).

The plasmon generation takes place inside the junction feeding the junction's eigenmode. Thus, we explore the exact location of the plasmon creation, which we hypothesize to be either inside the tunnel barrier or near the tunnel barrier such as inside the metal by physically accessing the mode via selective etching into the structure using focused ion beam milling (FIG. 4(c)). In addition, we aim to increase the outcoupling efficiency, by thinning down the emission blocking top metal layer, and further introduce a grating design to add momentum to facilitate plasmon-to-free-space coupling discussed below in contrast to studying only a random metal thinning on emission performance

Considering a skin depth of about 30 nm for gold at visible frequencies, only 1.8% of the EL reaches the top of the device for metal thicknesses of ˜100 nm. However, if the metal is too thin, resistive losses incur a voltage drop, reducing EL. The question is whether the thinning the top metal results in higher emission brightness. Gradually thinning the metal by a depth d, we find a linearly exponential EL increase matching the Beer-Lambert law (FIG. 4(a), (b)). Until this point we thinned the metal on the entire device pad area and utilized the aforementioned momentum matching from the metal roughness. In the limit of etching (removing) the entire pad, light creation would reduce to zero as no tunnel junction is formed.

However, if we etch only certain regions passing through the light-creating oxide layer, the resulting sharp edges facilitated the EL to scatter to free space by providing high wavevectors, but one loses light creation at these areas that were etched into the silicon (Region B, FIG. 4(b)). Thus, with outcoupling intensity in mind, optimization becomes a function of grating fill-factor; an initial test for a 1:1 fill factor shows a sharp drop for the case of etching deeply into the silicon (Region B, FIG. 4(b)). This is due to the lost photon creation and possible parasitic losses introduced by the gallium beam doping from the focused-ion-beam (FIB) milling process used, explaining the roll-off (d >150 nm, FIG. 4(b)). Another reason for the weak light emission intensity is attributed to the fact that both the hybrid photon plasmon and the surface plasmon modes are intrinsically nonradiative, because (a) their relative wavevector differs approximately by one order of magnitude and (b) both mode's wavevectors are larger (at least 2×) compared to that of free-space. However, the maximum output enhancement (33×) of the etched regions versus the metal pad no grating (MPNG) is observed when the metal is not entirely removed, but about 20-30 nm of metal remains (FIGS. 4(a), (b)).

Technologically a higher light output is desired for a light source. Since the top metal blocks the emission normal to the sample via absorption, flipping the metal insulator semiconductor (MIS) tunnel junction up-side-down to a SIM configuration (i.e. metal at bottom, and semiconductor on top) renders the use of established silicon-on-insulator (SOI) platforms unusable. Hence our design and approach is based on an SOI MIS configuration. Here, light emission is still limited by the top metal, which can be reduced, however by thinning the top metal. A second option to obtain higher light output is trivial and would be to increase the bias voltage. However thermal non-linearity leads to instabilities of the device, whereas the electric field breakdown voltage sets a fundamental upper voltage limit. Optically, the device operation involves three optical modes, which we discuss next from the inside out; (i) a hybrid plasmon polariton mode inside the MIS tunnel junction termed HPP mode, (ii) a SPP mode at the top of the metal-air interface, and (iii) free space photons leaving the device and being captured by the naked eye/detector/camera.

In operation both the HPP— and SPP modes are intrinsically nonradiative. Increasing the overall outcoupling efficiency requires a facilitating improved coupling between all three involved modes via wavevector matching, which can be achieved either by dispersion engineering, or via a grating structure. There are a variety of parameters effecting the MIS diode's light emission intensity (e) with respect to grating parameters (Λ, d, θ, and ϵ);

$${I}_{e} \approx \frac{P ( k , w )}{exp ( \frac{{λ}_{e}}{{L}_{x}} )} where {L}_{x} = \frac{1}{2 {k}_{i}} , k = K sin Θ \pm nG , G = \frac{2 π}{Λ} , k , {k}_{i} ∼ \frac{ϵ}{{t}_{ox}} \qquad ( 3 )$$

where w is the corresponding wavelength, k is the momentum, it=1,2,3, θ is the emission angle, λe is the effective wavelength, Λ is the grating period, tox and θ are the thickness and dielectric constant of oxide layer respectively. Increase in the light emission intensity (le) with respect to increase in θ and θ or decrease in tox and Λ are expected due to increase in k and decrease in Lx (eq. 3).

Furthermore, coupling the HPP mode efficiently into the light requires Λ˜λe where λe <80 nm (3 eV). However, the gratings duty cycle also effects the light emission efficiency (FIG. 4(c)). We investigated the grating impact via a grating shape dependent analysis. Here we assumed the metal thickness optimized case; the grating angle was kept constant as it only depends on the beam diameter of the focused-ion-beam (FIB) in the fabrication process, while the duty cycle was changed to create different grating shapes.

The advantage of this approach (changing duty cycle) is basically to eliminate the necessity of using tiny grating period (Λ˜λe where λe<80 nm (3 eV)), which may be challenging for during FIB ion milling, which could also lead to challenges in production yield for actual technology. The Lumerical simulation results with different duty cycle and its spectrum (FIG. 4(c)) suggests that there is an optimum duty cycle with respect to obtaining maximum light emission intensity.

The wall-plug quantum efficiency of the tunnel junction is given by the product of the internal light (here plasmon) generation efficiency times an outcoupling efficiency factor (Supporting Information). Previous work has investigated increasing these efficiencies; the wall-plug quantum efficiency increased from 4×10⁻⁷ to 3×10⁻⁵ (˜63-fold) and 9×10⁻⁷ to 1×10⁻⁴ (˜111-fold) with regard to prior systems.

A 40-fold increase in the quantum efficiency (wall-plug efficiency) is achieved in comparison to skin depth of metal via 10-fold increase in the internal efficiency and 4-fold increase in the outcoupling efficiency (FIG. 5(d)), while an absolute quantum efficiency is measured as on the order of 10⁻⁴.

FIGS. 5(a)-(c) show another example embodiment of the disclosure. Here, a grating 150 is applied to the top surface of Layer 3. Any suitable grating configuration can be provided, such as a single groove such as a line (FIG. 5(a)), sine-shape (FIG. 5(b), left) or square-shape (FIG. 5(b), right). FIG. 5(a) compares the outcoupling efficiency of a grating 150 with that of a thinned metal film. To improve the out-coupling ratio and gaining further into the silicon-SPP light source, we etched selective gratings into the device accessing the hybrid-plasmon-mode and facilitating coupling into free space (FIGS. 5(b), (c)). For instance, the EL originating from a single groove (FIG. 5(a), Areal x-groove=0.05 μm2) is about one order of magnitude brighter than the entire integrated power of the entire pad (49 μm2). However, the light emission can be observed with the naked eye (FIG. 1(e)), and an example video was captured by a CMOS camera. Furthermore, the tunnel probability into the light emission mode can be enhanced via the Purcell effect, reducing the tunnel current resistance. With experimental Purcell enhancements of about 100 being demonstrated, one could expect the conversion efficiencies to approach single digit percent range, which is just about 10×away from the predicted values.

Next, we analyze the increase in the quantum efficiency (ηwallplug) (40-fold) due to coupling effect between the grating's duty cycle and electric field enhancement. The outcoupling efficiency (ηoutcouple) increases with both the grating optimization (4-fold) or reduced top metal thickness. While the internal efficiency (ηint) increase (10-fold) due to a higher hot electron concentration facilitated by an electric field enhancement. Thus, the disclosure increases the internal quantum efficiency due to the interplay between changing the gratings duty cycle and subsequent electric field enhancement. This increase in internal efficiency in this work is attributed to the fact that, the duty cycle optimization enhances the electric field on the top thin metal layer, and this enhanced electric field on metal surface (probably the decay component) helps the electric field inside the oxide layer to have further increase in the hot electron creation.

This additional increase in the hot electron leads to increase in the internal efficiency and consequently higher intensity in the light emission. It therefore explains the efficiency ratio evolution with bias voltage between all three device types (FIG. 5(c)). Here, the outcoupling efficiency is constant and independent from the applied bias voltage. While the internal efficiency increases with applied bias voltage until the device enters the saturation region (˜5.1 V for sine shape grating, FIG. 5(b)). We find that a square-shaped grating (FIG. 5(b)) does not offer a significantly improved outcoupling efficiency over a thin metal (skin depth) layer because the island-like surface roughness of the polycrystalline deposited metal film (with an optimum thickness) already provides some momentum to facilitate outcoupling (FIG. 5(c)). Furthermore, we find that the coupling efficiency improvement over the nongrating case (thin metal layer (skin depth)) grows with bias (40-fold at 5.1 V) and drops after ˜5 V, which is likely due to joule heating and consequently thermal stress on the junction (FIG. 5(c)). This indeed is consistent with our experimental observations, where the device lifetime is inversely proportional to the bias voltage. An optimum operation voltage is at around 5.3 V for optimized light emission while keeping the thermal stress low.

We find a 10-fold increase in the internal plasmon-creating efficiency by coupling the electric field enhancement with that of an optimized grating design. This provided a 40-fold increase in the wall-plug quantum efficiency relative to the optimized metal thickness case. The increased outcoupling efficiency is independent of the applied voltage and is constant.

In order to gain further insights into the two components on the right-hand-side of (eq. 4), we perform numerical simulations to estimate the outcoupling efficiency to free space facilitated by the grating. The numerical simulations (FIG. 5(d)) suggest an outcoupling enhancement factor of about 4-fold. To confirm this, we treat this as an antenna problem by taking the ratio of an estimated source impedance (Rradiation) of the plasmon MIS mode without grating and the free-space impedance (z0=377Ω). Thus, averaging the effect of the grating (8×+3×)/2 5×improvement which matches our observed 4×well

$${R}_{radiation} = \frac{{ω}^{2}}{6 {πɛ}_{0} {c}^{3}} \cdot {a}^{2} = \sqrt{\frac{{μ}_{0}}{{ɛ}_{0}}} \frac{2 π}{3} {( \frac{a}{λ} )}^{2} \\ with \\ a ∝ {λ}_{MIS} ≅ {λ}_{0} \cdot [ \frac{1}{4} , \frac{1}{3} ] and {z}_{0} = \sqrt{\frac{{μ}_{0}}{{ɛ}_{0}}} = 377 Ω \\ {η}_{outcouple} \approx \frac{{R}_{radiation}}{{z}_{0}} = [ 12.5 , 33.3 \% ] \qquad ( 5 )$$

The outcoupling efficiency is calculated as 5x (eq. 5), and derived as 4×via Lumerical FDTD (FIG. 5(d)). These two findings are reasonably close to the ratio of 3.1× (between sine shape grating and no grating) at 8V (FIG. 5(c)) where the increase in efficiency are maximized and saturated for all three devices. All three devices are very close to failure due to joule heating and relatively high thermal stress (FIG. 6). That is why, the outcoupling efficiency can be estimated to be 4×. The relative efficiency increases up to 40.9× at 5.1 V (FIG. 5(c)), where the outcoupling efficiency is assumed to be 4×. That's why the increase in the internal efficiency is derived as 10×(40.9/4=10).

While the electric field across the tunnel oxide is high, the breakdown voltage for SiO2 is ˜3 V/nm. This matches our experiments in which devices above 8 V are mostly shorted and further explains the emission enhancement factor reduction with bias when comparing the junction's EL from a flat top metal with that when a grating was etched as discussed below with respect to FIG. 5(e).

Applying DC bias voltage between top metal and substrate (silicon) results in joule heating. This joule heating can cause device failure due to high thermal stresses at high temperatures. That's why thermal stresses should not exceed the ultimate tensile stress of each material used in building LETJ device. LETJ device should be operated below the critical/certain temperature for the sake of robust and reliable LETJ operation. In another words the safety factor shouldn't be less than 1 (allowable thermal stress/maximum thermal stress on the device) here.

Regarding applications, this tunnel source may find uses in communication where high sampling rates and footprint are of demand. Distinct from LEDs, the temporal response of this tunnel source is not governed by nanosecond carrier lifetimes known to semiconductors, but rather by the tunnel event itself, from Heisenberg's uncertainty principle, large optical bandwidths imply inelastic tunneling speeds on the order of 10s of femtoseconds. Our MIS tunnel source is a planar structure acting as a parallel plate capacitor. As a result, high modulation speed (>40 GHz) can be achieved with sufficiently thin tunnel oxides (0.6 nm). The latter is technologically achievable by adjusting the deposition cycle in the atomic-layer-deposition process. A video of a dynamically modulated junction that is slow-enough for the millisecond response time of digital camera is provided. Regarding footprint, we note that the internal hybrid photon plasmon mode of the junction is subdiffraction limited (λ/20), thus allowing for compact (10s of nanometers) light sources on-chip.

Because the emission originates from the rapidly-thermalized Fermi-sea of a semiconductor and into the conduction band of a metal, the limiting processes do not follow the standard rate equations of light emitters and lasers. From Heisenberg's uncertainty principle, large optical bandwidths imply inelastic tunneling speeds on the order of 10's of femtoseconds. Indeed, the temporal response of a tunnel event has been measured as short as 100 atto seconds. Comparing this to recombination lifetimes of direct and indirect bandgap semiconductors such as GaAs and Si, which are on the order of nanoseconds and milliseconds, respectively, we find that tunnel junctions may allow for a high modulation speed. With the delay of the actual tunnel being negligible, we analyze the electrical circuit-related constrains to understand the junction's actual response time. The limiting factor is related to resistive and capacitive (RC) effects of the junction itself.

The MIS tunnel source is a planar structure acting as a parallel plate capacitor (FIG. 7). Here, the relevant resistance in this case is not the line impedance but the resistance. For inelastic tunneling events to be dominant, the electron tunnel current must dominate the displacement current across the capacitor. Note, that the tunnel resistance scales inversely with area, whereas capacitance scales linearly, yielding an RC time constant invariant to area in an ideal case. However, the tunnel resistance scales exponentially with thickness, while the capacitance scales only linearly. As a result, high modulation speed (>40 GHz) can be achieved with sufficiently thin tunnel oxides (0.6 nm, FIG. 7). The latter is technologically achievable by adjusting the deposition cycle in the atomic-layer-deposition process (FIG. 7). The equivalent circuit of the MIS diode was derived as parallel RC and the cut off frequency of RC is;

$${f}_{c} = \frac{1}{2 π RC} , R = \frac{{V}_{bias}}{JA} , C = {ϵ}_{o} {ϵ}_{r} \frac{A}{{t}_{ox}}$$

where J is the tunneling current density and was derived using Silvaco where the silicon thickness is 200 nm for both PIS and MIS device. Replacing the top metal of the MIS junction with a polysilicon drops the speed to ˜8 GHz due to lower tunneling current originating from the higher resistance of the doped semiconductor vs. the metal (FIG. 7).

The metal serves a triple function in this light source; (i) metal confines the optical mode enabling device scalability via allowing for sub-diffraction limited modes as we have previously shown for hybrid plasmons, (ii) metal is a heat sync, since replacing the top metal with polysilicon raises the device temperature enabling higher modulation speeds (i.e. Pdissipated=E/bit×bitrate), and (iii) metal acts as an electrical contact allowing for low-voltage drops in the contacts leading up to the device. The latter is not possible for photonic devices as their optical loss from heavy-doped (low resistance) semiconductors is detrimental to the insertion loss devices. Interestingly, the modulation speed can be accelerated further by increasing the inelastic tunneling probability via the Purcell factor, which could be achieved by introducing nanoscale cavities. Such acceleration of emission processes will thus further decrease the tunneling resistance, hence increasing direct modulation speed. This also leads to an enhanced quantum efficiency and thus wall-plug efficiency, in analogy to the spontaneous emission factor reducing the laser threshold.

Layer 1 contacting the substrate has to be high thermal conductive layer, however for the best performance, all layers should have high thermal conductivity to direct the heat to the substrate (chip, wafer,). A high thermal conduction between device and substrate means, even at higher voltages, the device won't get too much heat. With the increase in the thermal conductivity constant of the material (Device Layers), the heat flux from device to substrate will increase. This in return results in less temperature on the device. Decrease in the temperature will result in decrease in the thermal stress (FIG. 6) and enables more voltage application that would bring higher light emission intensity (FIG. 3) and increase in quantum efficiency (FIG. 5(c)). One limitation for the present device is the thermal stresses due to relatively high temperature. The devices start to fail around 5.3V (FIGS. 5(c), 6). High thermal conduction between device and substrate means, even at higher voltages, the device won't get too much heat. With the increase in the thermal conductivity constant of the material (Device Layers), the heat flux from device to substrate will increase. This in return results in less temperature on the device. Decrease in the temperature will result in decrease in the thermal stress (FIG. 6) and enables more voltage application that would bring higher light emission intensity (FIG. 3) and increase in quantum efficiency (FIG. 5(c)).

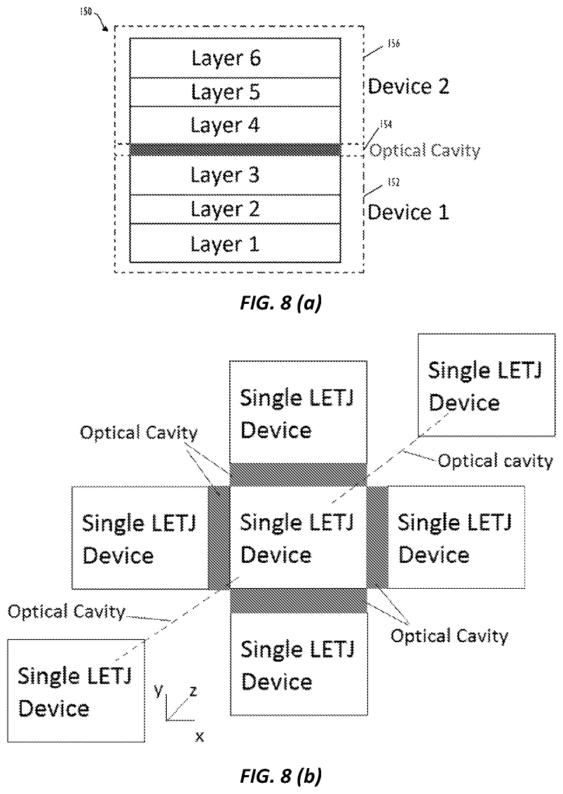

FIGS. 8(a), (b) show another non-limiting example embodiment of the invention. We could extend it into other material systems too to increase the light output. Moreover, one could design a single-electron tunnel structure that may be the first electrical driven quantum source (single photon emitter). Adding Purcell effect to LETJ Device to accelerate the spontaneous emission.

Any two or more LETJ devices can be connected to each other while creating an optical cavity between them to make much stronger light source like a laser. Two or more LETJ devices can be combined and facing each other at any one of 6 sides. This connection can be between any two devices on just one surface, or up to 6 surfaces. Moreover, this can be applied to any LETJ in this figure, in another words, we can have a 3D array structure like Rubik's cube having n number of Single LETJ Unit connected to each other via optical cavity. They emit the light towards each other and into the optical cavity.

Here the LETJ surfaces facing each other show a mirror effect. The optical cavity is placed between them so that the emitted light from one device will hit to another one's surface and bounce back. In this way it will increase the gain of the light emission intensity.

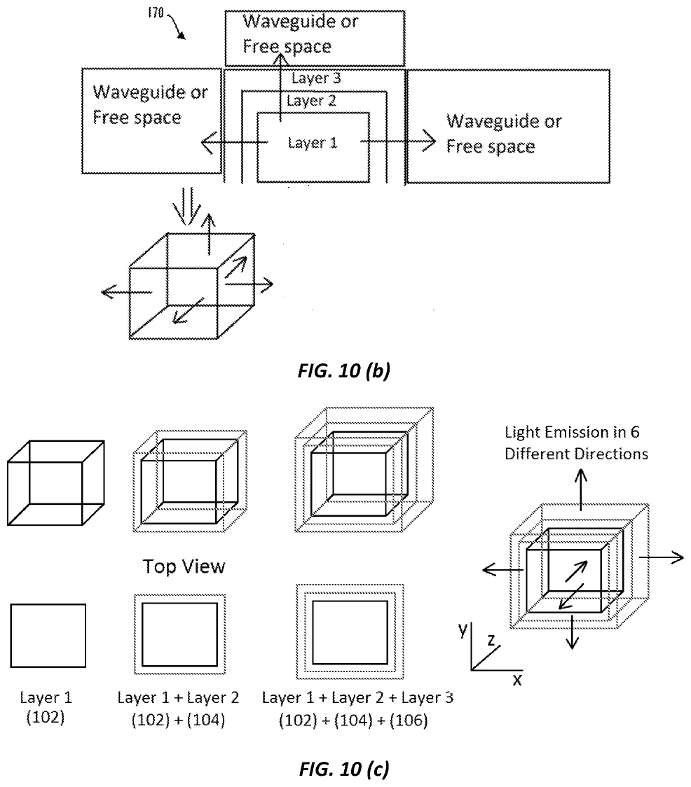

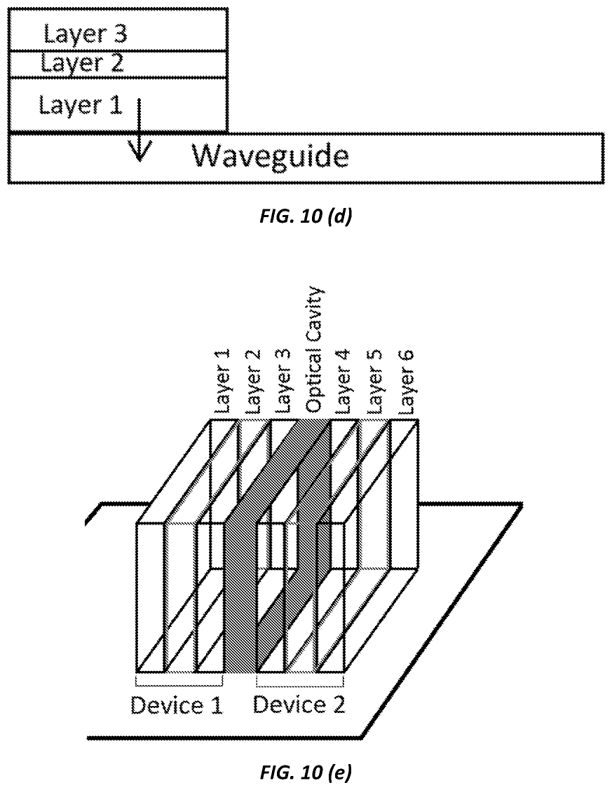

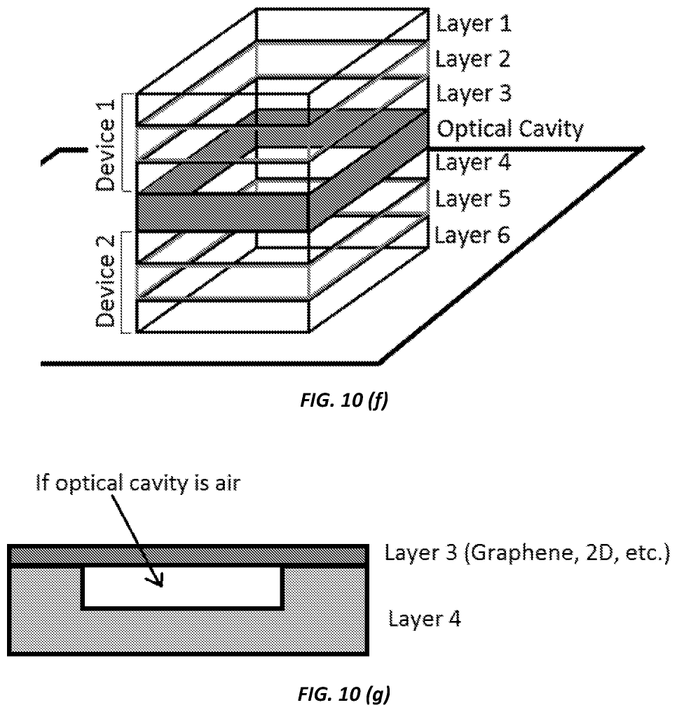

The optical cavity can be any type of medium, shape, structure and material (air, any other dielectric, semiconductor or metal, 0D, 1D, 2D, 3D, etc.). 2D layers here includes but not limited to ultrathin layers such as graphene, MoS₂, etc. If the optical cavity between two LETJ device is air, then the configuration of FIG. 10(g) or similar ones can be used in microfabrication steps to make sure we have a solid air gap between LETJ devices. Here Layer 3 and Layer 4 are the LETJ surfaces looking toward each other. As shown in FIG. 10(g), Layer 4 can have one or more upright portions that extend upwardly to form a recess. Layer 3 can extend between the upright portions over the recess, thereby forming the air gap optical cavity between Layer 3 and the top surface of Layer 4 between the upright portions.

Still other embodiments of the LETJ apparatus is shown in FIGS. 10(d)-(f), 12 which illustrate that LETJ devices and apparatus can be configured in any directions, such as vertical, horizontal, etc. In FIG. 10(d), the LETJ apparatus can be positioned with the layers and optical cavity arranged laterally side-by-side with one another, rather than one on top of the other as in earlier embodiments, and on a substrate. In addition, the LETJ apparatus can have two LETJ devices transversely positioned side-by-side with an optical cavity therebetween, rather than vertically on top of one another as in earlier embodiments. It is noted that FIG. 8(a) shows a 2D view and FIG. 10(e) shows both a 3D view and different orientations (vertical vs. horizontal). In FIG. 10(f), the optical cavity can be air.

Either or both of the LETJ devices 152, 156 can be the same as the LETJ apparatus 100 of FIGS. 1-7. The first LETJ device 152 has Layers 1, 2, 3 and emits light from the Layer 3 top surface into the optical cavity 154. The second LETJ device 156 has Layers 4, 5, 6, and emits light from the Layer 4 bottom surface into the optical cavity 154. The Layer 3 top surface directly contacts the optical cavity bottom, and the Layer 4 bottom surface directly contacts the optical cavity top, so that light (e.g., photons or phonons) can be communicated from Layers 3, 4 to the optical cavity 154. Here Layer 1, Layer 3, Layer 4 and Layer 6 can be either metal or semiconductor while Layer 5 and Layer 2 are each a dielectric layer. By having both Layers 3 and 4 emitting light into the optical cavity 154, the light emission intensity is increased. Thus, the Layer 3 top surface faces the Layer 4 bottom surface, but are separated from each other by a gap or spacing that forms the optical cavity 154. Thus, in this example, the optical cavity is air. However, in other embodiments the optical cavity 154 can be any medium or material that increase light emission gain. In one way, the medium can enable the light easily propagate inside cavity. The combination 150 can be enclosed in a housing, or each device 152, 156 can be included in a separate housing.

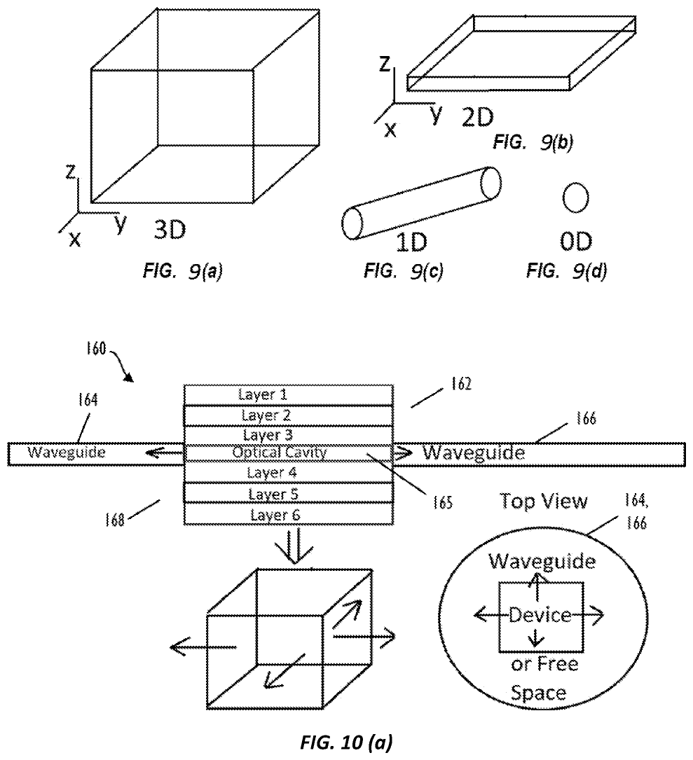

FIGS. 1(a), (c) show that light emission can be in any direction. For example, using 2D layers to build LETJ (FIGS. 1(c), 9(b)) including but not limited to ultrathin layers such as graphene, MoS₂, etc. The light emission can be in 1 or 2 different direction (FIG. 1(c)) in the same time. On the other hand, using 3D cubic shapes (FIGS. 1(a), 9(a)) to build LETJ can enable light emission up to 6 different directions (FIG. 1(a)) in the same time. FIG. 9 illustrates that the Layers can be 3D (FIG. 9(a)), 2D (Nanosheet, 2D materials like graphene, MoS₂, etc.) (FIG. 9(b)), 1D (nanotubes, Carbon nanotubes, etc.) (FIG. 9(c)) or 0D (Quantum Dot, Metal Nanoparticles (gold nanoparticles, etc.), dielectric nanoparticles, etc.) (FIG. 9(d)). In short, any combination in FIGS. 9(a)-(d) can be used to build LETJ device to enable light emission from only one side emission to up to all direction emission in the same time

Thus, light emission can be in any direction. For example, using 2D layers including but not limited to ultrathin layers such as graphene, MoS₂, etc. (FIG. 9(b)) enable light emission up to 2 different direction (FIG. 1(c) in the same time. While using 3D cubic shapes (FIG. 9(a)) enable light emission up to 6 different directions (FIG. 1(a)) in the same time. In short, any combination in FIGS. 9(a), (b), (c), (d) can be used to build LETJ device to enable light emission from only one side emission to up to all direction emission in the same time

The basic LETJ device 100 is a three-layer structure shown in FIG. 1. The LETJ can be built from any combination of 3D, 2D, 1D, and 0D. Some examples are shown in Table 2.

TABLE 2
example combination of Layers in LETJ Structure

| Layer 1 | Layer 2 | Layer 3 |
|---|---|---|
| 3D | 3D | 3D |
| 3D | 3D | 2D |
| 3D | 1D | 1D |
| 2D | 1D | 2D |
| 2D | 0D | 1D |
| 2D | 0D | 0D |
| 2D | 0D | 2D (Graphene) |
| (Graphene) | (dielectric | |
| | nanoparticle) | |

As shown in FIG. 8, the LETJ apparatus 150 can emit light into free space. Referring to FIG. 10(a), another embodiment of an LETJ apparatus 160 is shown having two LETJ devices 162, 168, an optical cavity 165 between the devices 162, 168, and one or more waveguides 164, 166. Each waveguide extends outward from either end of the optical cavity 165. Accordingly, a first waveguide 164 has an end that engages a first end of the optical cavity 165, and a second waveguide 166 has an end that engages a second end of the optical cavity 165. Light can pass out of the optical cavity 165 through the first and/or second ends to the first and/or second waveguides 164, 166. As shown by the arrows, the LETJ can emit light in all 5 directions. The layers can have any suitable shape, but in the breakout top view embodiment of FIG. 10(a) the layers are square or rectangular and the LETJ 160 emits light in four directions.

As shown in that top view, the waveguides 164, 166 can be placed at one or more of the four sides of the LETJ, or light can be emitted into free space. The circle represents the waveguide, and the square is the top view of the device 168, 162, 165. Here the top view of the waveguide can be square shape too. As shown, the device emits the light in 4 direction (side walls) and we are adding waveguide at one or more of those 4 directions. The devices 162, 168 and the cavity 165 can also have the same cross-sectional view.

FIG. 10(b) shows another example embodiment. Here, the LETJ assembly 170 has three layers that emits lights in five directions. FIG. 10(c) shows the application of the three layers being applied successively. In FIGS. 10(b), (c), the first layer has a square shape, the second layer is deposited over the first layer (top and four sides), and the third layer is deposited over the second layer (top and four sides), which provides light emission in ally direction. Here Layer 2 is dielectric layer and Layers 1, 3 are either semiconductor or metal. In the embodiment shown, the voltage is applied to the bottom surface of Layer 1, so the bottom surface of Layer 1 must be accessible. Thus, the second and third layers are not deposited on the bottom surface of the first layer, and light is not emitted downward from the bottom surface of Layer 1.

In an another embodiment the second and third layers can be partially disposed on the bottom surface or entirely disposed on the bottom surface with an opening to permit a lead or electrical contact with the bottom surface to apply a voltage to the bottom surface of the first layer, such that light can be emitted from all six sides, as shown in FIG. 1(a). In summary, the light emission can be in 6 directions and FIG. 10(b) and FIG. 10(d) can be combined or used separately.

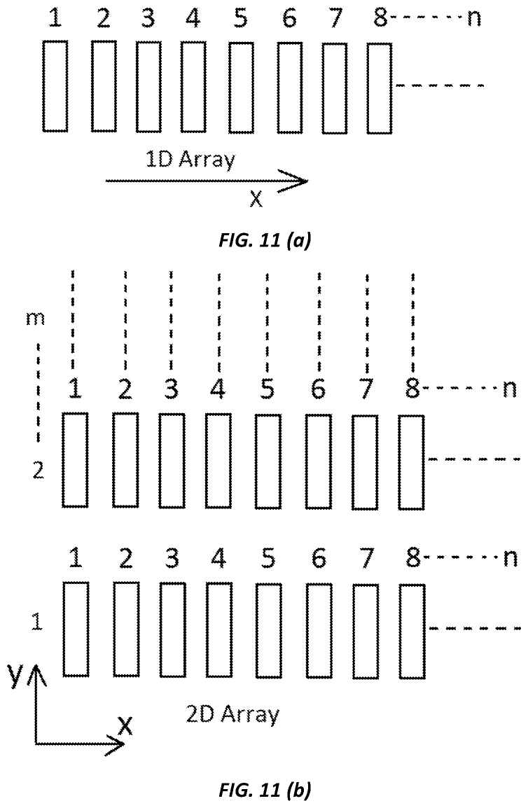

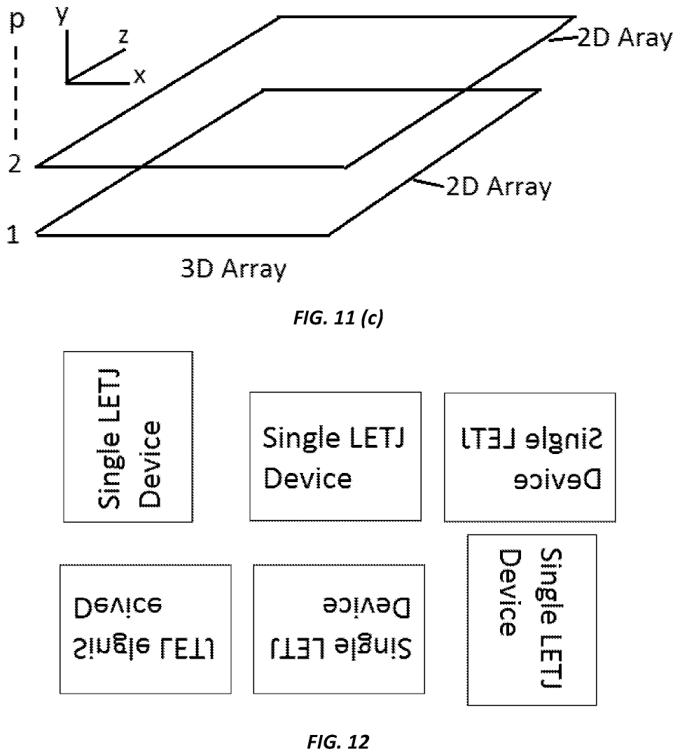

FIG. 11(d) shows another example embodiment. Here, the LETJ emitting light waveguide is placed underneath Layer 1. Thus, the light emission in FIG. 10(a) is in 4 directions, and a waveguide is connected at each of the 4 sides (except top and bottom). The light emission in FIGS. 10(b), (c) is in 5 directions, and a waveguide is connected at all 5 direction (except bottom). The light emission in FIG. 10(d) is towards the bottom surface here and waveguide is connected to the bottom surface. These three different configurations can be combined or used separately.

FIG. 11(a) shows a 1D array configuration of a plurality of LETJ devices, which can be for example the LETJ device 100. The devices are arranged linearly next to one another. In FIG. 11(b), the devices are arranged in a 2D array configuration with the devices aligned in rows and columns. Here, the purpose is to use 2D array rather than 1D array (FIG. 5(b) and FIG. 11(a)) to increase the light emission intensity and quantum efficiency.

FIG. 11(c) shows 3D array configuration, where 2D arrays are aligned on each other. This will enable further increase in the light emission intensity and quantum efficiency in comparison to 2D array (FIG. 11(b))

Another embodiment of the present disclosure uses Indium Titanium Oxide (ITO) to build a transparent LETJ device. For example, Layer 1 and Layer 3 can be ITO and Layer 2 can be SiO2 in FIG. 1. A transparent device can be useful, such as for a transparent display. It enables the circuit and devices transparent, in this way the devices can be imported on transparent flexible substrate. Display can be one example, contact lens can be another example, etc.

It is further note that the bias voltage changes physical/electrical/chemical/etc. features of one or more of the layers. For instance, graphene chemical potential change with the applied bias voltage, etc., to change the LETJ's emission property, such as the emission frequency, emission intensity, etc. In addition, any physical or chemical changes in environment (temperature, external light source (can be any wavelength and frequency), humidity, pressure, etc.) changes the physical, electrical or chemical features of said first, second and/or third layers. If this happens during the device operation (light emission due to bias voltage application) then it changes the LETJ's emission property such as the emission frequency, emission intensity, etc. In that embodiment, the LETJ can be utilized, for example, as a sensor and placed in a housing.

In addition, the LETJ can be configured in 2D array rather than 1D array (FIG. 7). This can also be used to create antenna coupled structure to increase quantum efficiency. Here, the purpose is to use 2D array rather than 1D array (FIGS. 5(b), 11(a)) to possibly increase the light emission intensity and quantum efficiency, such as the antenna coupled structure.

It will be apparent to those skilled in the art having the benefit of the teachings presented in the foregoing descriptions and the associated drawings that modifications, combinations, sub-combinations, and variations can be made without departing from the spirit or scope of this disclosure. Likewise, the various examples described may be used individually or in combination with other examples. Those skilled in the art will appreciate various combinations of examples not specifically described or illustrated herein that are still within the scope of this disclosure. In this respect, it is to be understood that the disclosure is not limited to the specific examples set forth and the examples of the disclosure are intended to be illustrative, not limiting.

As used in this specification and the appended claims, the singular forms “a”, “an” and “the” include plural referents, unless the context clearly dictates otherwise. Similarly, the adjective “another,” when used to introduce an element, is intended to mean one or more elements. The terms “comprising,” “including,” “having” and similar terms are intended to be inclusive such that there may be additional elements other than the listed elements.

Additionally, where a method described above or a method claim below does not explicitly require an order to be followed by its steps or an order is otherwise not required based on the description or claim language, it is not intended that any particular order be inferred. Likewise, where a method claim below does not explicitly recite a step mentioned in the description above, it should not be assumed that the step is required by the claim.

It is noted that the description and claims may use geometric or relational terms, such as beneath, top, bottom, linear, parallel, end, planar, flat, square, rectangular, etc. These terms are not intended to limit the disclosure and, in general, are used for convenience to facilitate the description based on the examples shown in the figures. In addition, the geometric or relational terms may not be exact. For instance, walls may not be exactly parallel to one another because of, for example, roughness of surfaces, tolerances allowed in manufacturing, etc., but may still be considered to be parallel.

1. A Light Emitting Tunnel Junction (LETJ) comprising:
a first layer;
a second layer;
a third layer disposed between said first layer and said second layer to form a junction between said first layer and said second layers;
wherein each of said first and second layers is comprised of any one of the following materials and/or heterojunctions: metal, semiconductor, oxide, dielectric, semi-metal, topological insulator, Weyl fermion material, or any heterojunction thereof;
whereas said third layer comprises any one of the following materials: semiconductor, oxide, dielectric, air, free-space, gap; and
a power supply providing a bias voltage to said first layer and said second layer, wherein said bias voltage triggers charge carrier tunneling across said junction to induce light creation, whereas such light can be a photon, a light package comprising surface plasmon polariton or a combination thereof including single or plurality of light packages, whereas in the single light package case a quantum source is created.

2. A Light Emitting Tunnel Junction (LETJ) comprising:
a first layer;
a second layer;
a third layer disposed between said first layer and said second layer to form a junction between said first layer and said second layers;
wherein each of said first and second layers is comprised of any one of the following materials and/or heterojunctions: metal, semiconductor, oxide, dielectric, semi-metal, topological insulator, Weyl fermion material, or any heterojunction thereof;
whereas said third layer comprises any one of the following materials: semiconductor, oxide, dielectric, air, free-space, gap; and
wherein any physical, electrical or potential changes in environment alters the physical, electrical or chemical features of said first, second and/or third layers.

3. A Light Emitting Tunnel Junction (LETJ) comprising:
a first layer having a first layer top surface and a first layer bottom surface;
a second layer having a second layer top surface directly in contact with the first layer bottom surface, and a second layer bottom surface;
a third layer having a third layer top surface directly in contact with the second layer bottom surface, and a third layer bottom surface; and
a power supply providing a bias voltage to said first layer and said third layer, whereby the bias voltage is selectively applied to induce a photon or phonon emission from the first layer.

4. The LETJ of claim 1, wherein said first layer has a first layer top surface and a first layer bottom surface and said second layer has a second layer top surface and a second layer bottom surface, and said bias voltage is applied to the first layer top surface and the second layer bottom surface.

5. The LETJ of claim 4, wherein said dielectric layer has a dielectric top surface directly contacting the first layer bottom surface, and said dielectric layer has a dielectric bottom surface directly contacting the second layer top surface.

6. The LETJ of claim 1, wherein said dielectric layer forms an electrically biased barrier between said first metal or semiconductor layer and said second metal or semiconductor layer, whereby an electron tunneling from said first layer to said second layer releases said light creation.

7. The LETJ of claim 3, further comprising a material cladding layer or layers, whereas said cladding layer or layers comprises material having a single layer or multi-material layers.

8. The LETJ of claim 7, wherein the material comprises metal, dielectric or a combination of metal and dielectric.

9. The LETJ of claim 3, further comprising of an optical, plasmonic, or hybrid-thereof optical cavity or resonator arranged to receive the light from said LETJ.

10. The LETJ of claim 3, further interfacing the LETJ with a wave duct wherein said wave duct comprises an integrated photonics waveguide, or optical fiber, or optical system.

11. The LETJ of claim 1, further comprising:
a fourth metal or semiconductor layer having a fourth layer top surface and a fourth layer bottom surface;
a fifth dielectric layer having a fifth layer top surface directly in contact with the fourth layer bottom surface, and a fifth layer bottom surface; and
a sixth metal or semiconductor layer having a sixth layer top surface directly in contact with the fifth layer bottom surface, and a sixth layer bottom surface,
whereby an added bias voltage is selectively applied to induce a photon or phonon emission from the fourth layer.

12. The LETJ of claim 3, said LETJ comprising a 3D cubic shape and can emit the light, in general, in any of the six spatial directions.

13. The LETJ of claim 3, wherein said first and second layers can comprise a 3D, 2D, 1D or 0D structure, or any combination thereof.

14. The LETJ of claim 3, wherein the bias voltage changes the physical, electrical or potential property of said first and/or third layers.

15. The LETJ of claim 14, wherein the potential property comprises a Fermi level of said first, second and/or third layers.

16. The LETJ of claim 14, wherein properties of the material include potential change between said first layer and said third layer, and/or emission property including light package emission frequency or emission intensity.
